(19) United States
(12) Patent Application Publication
(10) Pub. No.: US 2023/0409327 A1
(43) Pub. Date: Dec. 21, 2023

(54) DATA REFORMAT OPERATION

(71) Applicant: MELLANOX TECHNOLOGIES, LTD., Yokneam (IL)

(72) Inventors: Dotan David Levi, Kiryat Motzkin (IL); Eliel Peretz, Kiryat Motzkin (IL); Richard Graham, Knoxville, TN (US); Daniel Marcovitch, Yokneam Illit (IL); Gil Bloch, Zichron Ya'acov (IL); Roee Moyal, Yokneam Illit (IL); Eyal Srebro, Kfar Yehoshua (IL); Sean Midthun Pieper, Waldport, OR (US)

(21) Appl. No.: 17/844,461

(22) Filed: Jun. 20, 2022

(51) Int. Cl. G06F 9/30; G06F 9/445

(52) U.S. Cl. CPC G06F 9/30192; G06F 9/30025; G06F 9/44542

(57) ABSTRACT

Devices, methods, and systems are provided. In one example, a device is described to include circuitry that collects data received from a data source, references a descriptor that describes a data reformat operation to perform on the data received from the data source, reformats the data received from the data source according to the data reformat operation, and provides the reformatted data to the data target via the second device interface.

### FIELD OF THE DISCLOSURE

The present disclosure is generally directed toward networking devices and, in particular, toward enabling data reformat operations in networking devices.

### BACKGROUND

Data reformatting is a process of reorganizing a given set of data into a different layout. A matrix transpose is one example of a data reformat operation where a two-dimensional array with homogenous element size is reformatted. Other examples of a data reformat operation include transposing a two-dimensional array with a non-homogenous element size. Another example of data reformatting corresponds to changing the way that data is scattered (e.g., changing endianity of the data).

A commonality between many forms of data reformat operations is that source data is arranged in a buffer with a high degree of contiguity. When a Central Processing Unit (CPU) or Graphics Processing Unit (GPU) of a host device or other computational node is actively performing a data reformat operation, the resources of the CPU or GPU performing the data reformat operation are not free to perform other tasks. Other inefficiencies associated with performing a data reformat operation at a CPU or GPU of a host device or other computational node may also arise. A data reformat operation may also consume memory bandwidth as the data needed to support the operation needs to be read and then written again to memory.

### BRIEF SUMMARY

Embodiments of the present disclosure aim to solve the above-noted shortcomings associated with solely performing a data reformat operation at a CPU. In some embodiments, some or all data reformat operations that would traditionally be performed at a CPU (e.g., to accommodate application-level requirements or transport-level requirements) may be offloaded to a network device. Examples of network devices that may be configured to offload data reformat operations may include, without limitation, a switch, a Network Interface Controller (NIC), a network adapter, a DPU, an Ethernet card, an expansion card, a Local Area Network (LAN) adapter, a wireless router, physical network interface, a network border device (e.g., Session Border Controller (SBC), firewall, etc.) or similar type of device configured to perform network or data transfer processes. Data reformatting may be performed at a sender-side interface, a receiver-side interface, within an application residing between a data source and a data target, within an application residing at a data source, and/or within an application residing at a data target.

Some existing NICs, for example, can map a single memory region to arbitrary physical memory locations. At first glance this seems to enable any data reformat implementation. However, this suffers from two drawbacks: (1) a large data structure will require complex element location description (e.g., multiple {offset, size} elements) and (2) when shuffling small data elements (e.g., 8B or less)—this will require multiple Peripheral Component Interconnect express (PCIe) reads, which wastes PCIe bandwidth and encounters multiple bottlenecks in both the NIC and the CPU.

As discussed above, a data reformat operation may be characterized by a high level of contiguity in memory of a data source. A data reformat offload can utilize this characteristic to provide an improved reformat rate and improve the operational efficiency of the overall computational/communication system. As an example, a data reformat operation can be performed with a single read and a single write. As another example, a data reformat operation may be performed without additional read and writes that are already used for networking purposes.

Illustratively, and without limitation, a network device is disclosed herein to include a data reformat unit that is configured to receive a large portion of data to be reformatted along with a descriptor describing a reformat pattern. The data reformat unit may output reformatted data using dedicated circuitry, while maintaining a high reformat rate. Output of the data reformat unit (e.g., reformatted data) may be written to one or more locations in memory or may be transmitted over a communication network. In some embodiments, such as High Performance Computing (HPC) environment, a data reformat operation may be performed as part of a communication scheme and may be hidden in a communication library. It may be possible to represent or modify data reformat operations without requiring a change at an application level.

If a data reformat unit as depicted and described herein is added to a NIC to store the data locally, reformat, then send onto the wire, it becomes possible to offload CPU utilization and possibly avoid unwanted CPU surges. Offloading the data reformat operations to the NIC, for example, may also extend to the data targets, which may implement any number of different processes. This means that a device performing the data reformat operation and a data transfer operation can be located remotely from the data source and/or data target, effectively improving scalability. This advantage is particularly highlighted if the data reformat is needed because of the fact that a different processor has a different architecture. In such a scenario, the data reformat operation performed in the NIC can substantially eliminate the need for the application to know anything about the other machine architecture. If, for example, the other machine has a different endianity, the NIC can offload the endianity transformation between the different architectures. By offloading the transformation to the data reformat unit, the application can remain unaware of the endianity restrictions existing in other application versions, flavors or instances. The offload can be done on the transmitting NIC and/or the receiving NIC. Another scenario that could benefit from the offload is one in which different machines use different floating point format precision.

While a number of data reformatting operations are described, it should be appreciated that a data reformat unit can also be configured to perform data reformat operations without departing from the scope of the present disclosure. Indeed, a data reformat unit may be configured to perform a data reformatting operation (e.g., an operation where a layout/organization of the data is changed, but not information is lost or removed) and/or a data reformat operation (e.g., an operation where data is reorganized in a way so as to increase data efficiency, performance, etc.). A more specific but non-limiting example of a data reformatting operation may correspond to changing an endianity. Another example of a data reformatting operation may correspond to changing data to accommodate compatibility between different application versions or flavors (e.g., reformatting data from a format used by a first version of an application into a format used by a second version of the application). A more specific but non-limiting example of a data reformat operation may correspond to reducing the bit-depth from a floating-point to integer accuracy.

Another example of a data reformat operation includes converting image representation layout. For example, data formatted in a single plane image includes, for each pixel, all the color channels adjusted to one another such as an RGB, YUV, or YCbCr representation for each pixel. Another data representation layout for an image may include multiple planes of a single channel image, e.g. each plane includes data for a single color channel, and three planes are used to represent a single image. The data reformat unit may convert data received in a single plane layout to data represented in multiple planes layout (the concept of multiple planes representation is depicted in U.S. Pat. No. 11,252,464 to Levi et al.)

In an illustrative example, a network device is disclosed that includes: a device interface that receives data from at least one data source; and a data reformat unit that collects the data received from the at least one data source, receives a descriptor that describes a data reformat operation to perform on the data received from the at least one data source, performs the data reformat operation on the collected data to produce reformatted data, and provides the reformatted data to at least one data target.

In some embodiments, the data reformat operation is done according to a descriptor provided by the at least one data source.

In some embodiments, the data reformat unit includes a processor and memory, where the memory is used to store the data received from the at least one data source until a predetermined amount of data is collected, and where the processor performs the reformat operation on the predetermined amount of data stored in memory.

In some embodiments, the at least one data source includes a host memory device, peer memory device, and/or on-network device memory.

In some embodiments, the data is received in a plurality of network packets.

In some embodiments, the at least one data target includes a plurality of data targets.

In some embodiments, the at least one data target includes a host memory device, a peer memory device, and/or an on-network device memory.

In some embodiments, the at least one data target is located remotely from the data reformat unit. Illustratively, the network device may further include a second device interface that couples the network device with the data target, where the device interface includes a communication port and where the second device interface also includes a communication port.

In some embodiments, the at least one data source is located remotely from the data reformat unit.

In some embodiments, the descriptor includes a work queue element posted to a work queue.

In some embodiments, the descriptor is obtained from a memory device of the reformat unit and includes a memory region description that is usable to perform multiple reformat operations.

In some embodiments, the descriptor is received in a network packet via the device interface.

In some embodiments, the descriptor is received as part of a Remote Direct Memory Access (RDMA) request or an application-level request.

In some embodiments, the device interface and the reformat unit are provided as part of a NIC or a card including a NIC.

In some embodiments, the device interface and the reformat unit are provided as part of a network switch.

In some embodiments, an application receiving the reformatted data is unaware of the data reformat performed by the data reformat unit. Unawareness is a strong advantage for software ecosystems and can mean that the application doesn't have to change, be redesigned, and/or re-tested when the data format is changed. Format-unawareness allows scalability and agility of the applications or distributed applications. Different applications that were targeted to perform the same semantic operations that were not designed using a single data format, can be interoperable using a network device as described herein. Instead of changing an application to support different data formats, the application may remain unchanged and all data format operations are aligned by the data reformat unit.

In some embodiments, the reformatted data is provided to the at least one data target via the device interface.

In some embodiments, the reformatted data includes a same number of bits as the collected data.

In some embodiments, the at least one data source includes a network edge device.

In some embodiments, the device interface includes a serial data interface and the data is received from the at least one data source via a serial communication protocol.

In another example, a system is disclosed that includes: a device interface that receives data from at least one data source; circuitry; and memory coupled with the circuitry, where instructions stored in memory enable the circuitry to collect the data received from the at least one data source, receive a descriptor that describes a data reformat operation to perform on the data received from the at least one data source, perform the data reformat operation on the collected data to produce reformatted data and according to requirements of at least one data target, and then provide the reformatted data to the at least one data target.

In yet another example, a format-aware data transfer device is disclosed that includes: a first device interface enabling communications with a data source; a second device interface enabling communications with a data target; and a data reformat unit. The data reformat unit may include a processor and/or circuitry, where the processor and/or circuitry collects data received from the data source, references a descriptor that describes a data reformat operation to perform on the data received from the data source, reformats the data received from the data source according to the data reformat operation, and provides the reformatted data to the data target via the second device interface.

In some embodiments, the descriptor is stored in a local memory or a remote memory and described by a match criteria on the data. Examples of a match criteria include network flow 5-tuple information or a portion thereof, application-layer packet header (in the 7-layer OSI model), VLAN tags, source address. It should be appreciated that this memory can reside on the host node and/or the NIC. In other words, the NIC can reside both remotely or locally.

In some embodiments, the descriptor is provided by the data source and/or data target.

In some embodiments, the descriptor is referenced for a plurality of data reformat operations.

In some embodiments, the first device interface includes a communication port.

In some embodiments, the second device interface includes an additional communication port.

In some embodiments, the second device interface connects to a communication network.

In some embodiments, the first device interface connects to a communication network.

In some embodiments, the data source includes a neural network. In a further aspect, the data target may include a second neural network that is different from the neural network. Furthermore, the data received from the data source may include a first tensor layout and the reformatted data may include a second tensor layout that is different from the first tensor layout. In some embodiments, the data received from the data source includes image data.

In some embodiments, the data received from the data is formatted for use by a first version of an application and the reformatted data is formatted for use by a second version of the application.

In some embodiments, the data reformat operation includes at least one of a matrix transpose, a non-homogenous transpose, a data type conversion, a tensor layout conversion, color channel separation, and a change in endianity. In some embodiments, the data source includes a first memory sub-system and the data target includes a second memory sub-system.

In some embodiments, the processor of the data reformat unit is further configured to perform the data reformat operation on the data received from the data source and produce first reformatted data for the data source as well as second reformatted data from an additional data source, where the first reformatted data is formatted differently from the second reformatted data.

In some embodiments, the data reformat unit is provided at a sender-side network device. In some embodiments, the data reformat unit is provided at a receiver-side network device. In some embodiments, the data reformat unit is provided within an application.

In some embodiments, the descriptor defines a requirement for endianness.

In some embodiments, the first device interface includes a communication port connected with a communication network. The second device interface may include a communication port connected with the communication network or another communication network.

In some embodiments, at least one of the data source and data target include a peripheral device.

In some embodiments, the descriptor is stored in memory that is coupled with the circuitry or in a remote memory.

In some embodiments, the descriptor is received from a control device that is different from the data source and the data target.

In yet another example, a system is provided that includes: circuitry and a memory coupled with the circuitry, where the circuitry is configured to collect data received from a data source in the memory, reference a descriptor that describes a data reformat operation to perform on the data received from the data source, reformat the data received from the data source according to the data reformat operation, and provide the reformatted data to a data target.

Additional features and advantages are described herein and will be apparent from the following Description and the figures.

### BRIEF DESCRIPTION OF THE SEVERAL VIEWS OF THE DRAWINGS

The present disclosure is described in conjunction with the appended figures, which are not necessarily drawn to scale:

FIG. 1A is a block diagram illustrating a computing system in accordance with at least some embodiments of the present disclosure;

FIG. 1B is a block diagram illustrating an alternative arrangement of a computing system in accordance with at least some embodiments of the present disclosure;

FIG. 1C is a block diagram illustrating yet another alternative arrangement of a computing system in accordance with at least some embodiments of the present disclosure;

FIG. 2 is a block diagram illustrating details of a network device operating in conjunction with a control initiator and work initiator in accordance with at least some embodiments of the present disclosure;

FIG. 3 is a block diagram illustrating additional details of a data reformat unit in accordance with at least some embodiments of the present disclosure;

FIG. 4 is a block diagram illustrating additional details of a data reformat unit in accordance with at least some embodiments of the present disclosure;

FIG. 5 is a block diagram illustrating additional details of a data reformat unit in accordance with at least some embodiments of the present disclosure;

FIG. 6 is a block diagram illustrating additional details of a data reformat unit in accordance with at least some embodiments of the present disclosure;

FIG. 7A illustrates one example of an operation that may be performed by a data reformat unit in accordance with at least some embodiments of the present disclosure;

FIG. 7B illustrates another example of an operation that may be performed by a data reformat unit in accordance with at least some embodiments of the present disclosure;

FIG. 8 illustrates another example of an operation that may be performed by a data reformat unit in accordance with at least some embodiments of the present disclosure;

FIG. 9 illustrates another example of an operation that may be performed by a data reformat unit in accordance with at least some embodiments of the present disclosure;

FIG. 10 illustrates another example of an operation that may be performed by a data reformat unit in accordance with at least some embodiments of the present disclosure;

FIG. 11 illustrates another example of an operation that may be performed by a data reformat unit or multiple data reformat units in accordance with at least some embodiments of the present disclosure;

FIG. 12 illustrates another example of an operation that may be performed by a data reformat unit in accordance with at least some embodiments of the present disclosure;

FIG. 13 illustrates another example of an operation that may be performed by a data reformat unit in accordance with at least some embodiments of the present disclosure;

FIG. 14 illustrates another example of an operation that may be performed by a data reformat unit in accordance with at least some embodiments of the present disclosure;

FIG. 15 illustrates another example of an operation that may be performed by a data reformat unit or multiple data reformat units in accordance with at least some embodiments of the present disclosure;

FIG. 16 illustrates another example of an operation that may be performed by a data reformat unit or multiple data reformat units in accordance with at least some embodiments of the present disclosure;

FIG. 17 illustrates another example of an operation that may be performed by a data reformat unit in accordance with at least some embodiments of the present disclosure;

FIG. 18 is a flow diagram illustrating a method of operating a network device in accordance with at least some embodiments of the present disclosure; and

FIG. 19 is a block diagram illustrating another arrangement of a computing system in accordance with at least some embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

It will be appreciated from the following description, and for reasons of computational efficiency, that the components of the system can be arranged at any appropriate location within a distributed network of components without impacting the operation of the system.

Furthermore, it should be appreciated that the various links connecting the elements can be wired, traces, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a Printed Circuit Board (PCB), or the like.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means: A alone, B alone, C alone, A and B together, A and C together, B and C together, or A, B and C together.

The term “automatic” and variations thereof, as used herein, refers to any appropriate process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The terms “determine,” “calculate,” and “compute,” and variations thereof, as used herein, are used interchangeably and include any appropriate type of methodology, process, operation, or technique.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

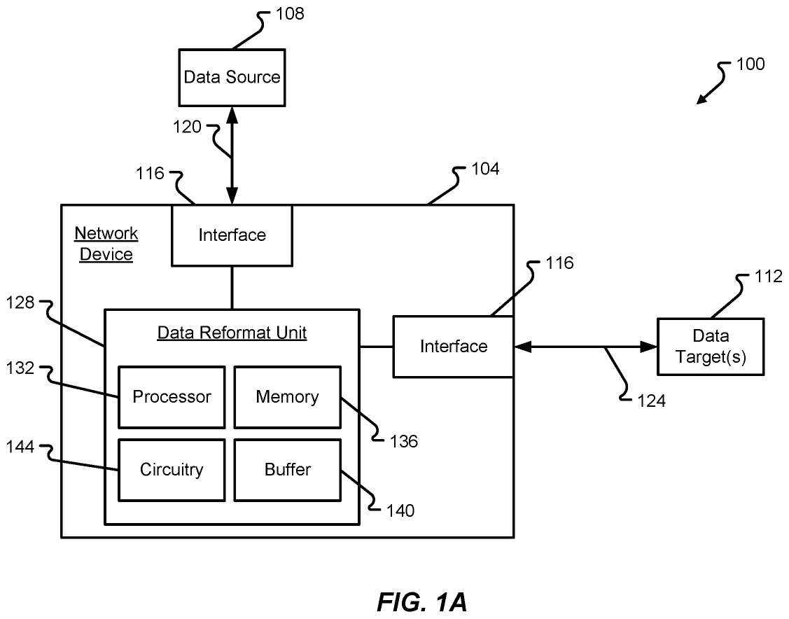

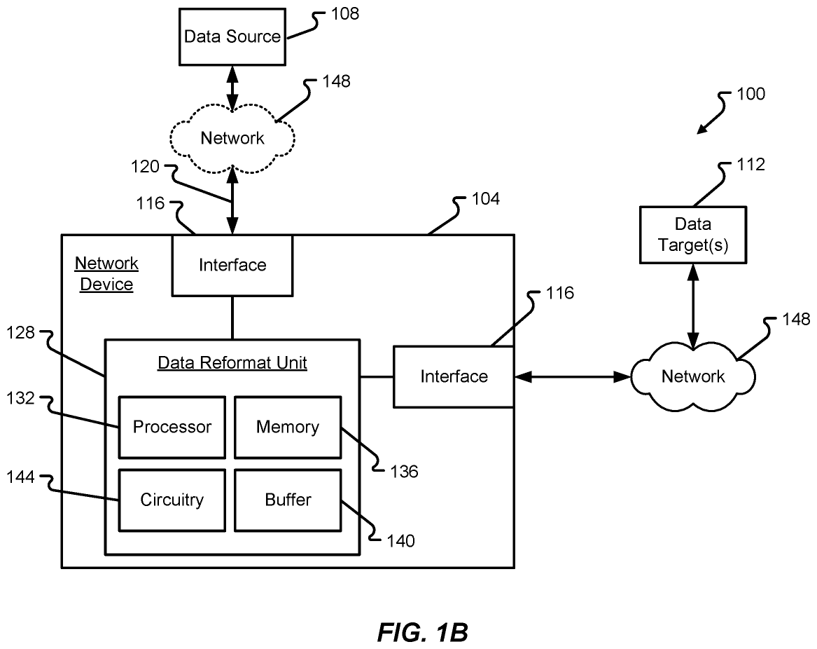

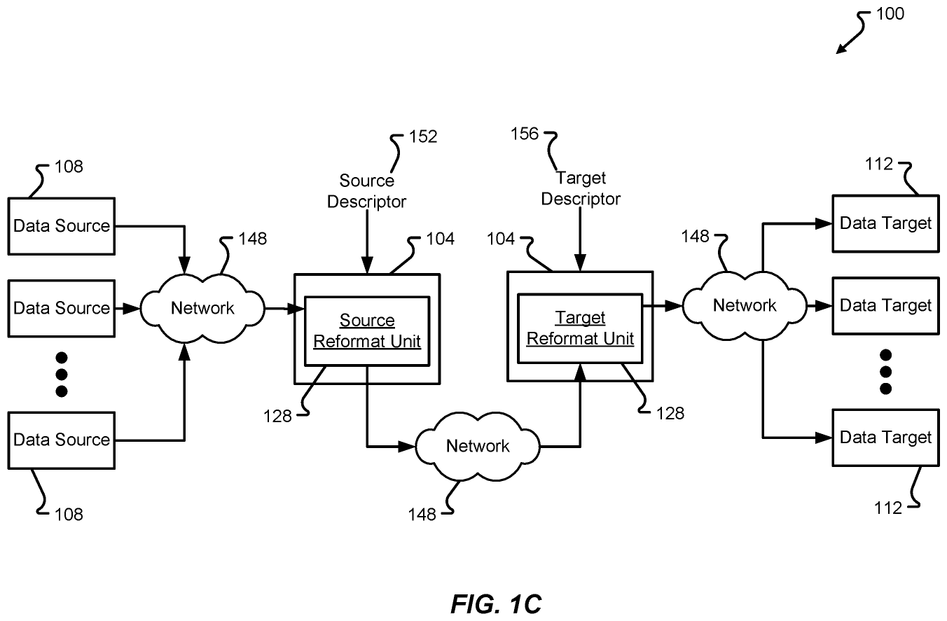

Referring now to FIGS. 1-18, various systems and methods for implementing data shuffling in a computing or communication system will be described in accordance with at least some embodiments of the present disclosure. As will be described in more detail herein, a data reformat unit is contemplated that is configured to receive data, perform a data reformat operation on the data to produce reformatted data according to requirements defined in a reformat descriptor, and then provide or transmit the reformatted data to the data target. Certain examples of a data reformat unit will be described as being implemented in a network device such as switch, a NIC, a network adapter, an Ethernet card, an expansion card, LAN adapter, physical network interface, a wireless router, a network border device, or the like. It should be appreciated that the data reformat unit that receives the data and performs a data reformat operation may reside in a network device that is acting as a transmitting network device or in a network device that is acting as a receiving network device. In other words, the network device may correspond to a transmitter or receiver and the data reformat operation may be performed prior to transmitting data across a communication network or after the data has been received from a communication network. Said another way, embodiments of the present disclosure contemplate a source reformat unit configured to reformat source data and/or a target reformat unit configured to reformat target data.

Referring initially to FIGS. 1A through 1C, a first illustrative computational system 100 is shown in which a network device 104 is configured to communicate with a data source 108 and a data target 112 or multiple data targets 112. The network device 104 may include any type of device used to facilitate machine-to-machine communications. As mentioned above, the network device 104 may include one or more of a switch, a NIC, a network adapter, an Ethernet card, an expansion card, LAN adapter, physical network interface, a wireless router, a network border device, or the like. Alternatively or additionally, the network device 104 may be referred to as a data transfer device and, in some embodiments, may correspond to a format-aware data transfer device. In some embodiments, the network device 104 is provided with a data reformat unit 128 that is configured to offload a data reformat operation from the data source 108 and/or data target(s) 112. Specifically, the network device 104 may be configured to perform data transfer functions as well as data reformat operations, thereby offloading certain data reformat operations from the data source 108 and/or data target(s) 112.

The network device 104 may be connected with the data source 108 via a first device interface 116. The first device interface 116 may enable communications between the network device 104 and the data source 108 via a first communication link 120. The first communication link 120 may include a wired connection, a wireless connection, an electrical connection, etc. In some embodiments, the first communication link 120 may facilitate the transmission of data packets between the network device 104 and the data source 108 via one or more of electrical signals, optical signals, combinations thereof, and the like. The data packets may carry data from the data source 108 to the network device 104, which is intended for transmission to the data target(s) 112. In other words, the network device 104 may enable communications between the data source 108 and the data target(s) 112 and may further utilize the data reformat unit 128 to perform a data reformat operation while data is being transferred from the data source 108 to the data target(s) 112. It should be appreciated that the system bus (e.g., the pathway carrying data between the data source 108 and data target(s) 112) may include, without limitation, a PCIe link, a Compute Express Link (CXL) link, a high-speed direct GPU-to-GPU link (e.g., an NVlink), etc.

The network device 104 may be connected with one or more data targets 112 via a second device interface 116. The second device interface 116 may be similar or identical to the first device interface 116. In some embodiments, a single device interface 116 may be configured to operate as the first device interface 116 and the second device interface 116. In other words, a single device interface 116 may connect the network device 104 to the data source 108 and the data target(s) 112. In some embodiments, however, different physical devices may be used for the different interfaces, meaning that the first device interface 116 may correspond to a first physical device that is different from a second physical device operating as the second device interface 116. The second device interface 116 may enable communications between the network device 104 and data target(s) 112 via a second communication link 124. As can be appreciated, the second communication link 124 may include one or multiple different communication links depending upon the number of data targets in the data target(s) 112. Much like the first communication link 120, the second communication link 124 may include a wired connection, a wireless connection, an electrical connection, etc. In some embodiments, the second communication link 124 may facilitate the transmission of data packets between the network device 104 and the data target(s) 112 via one or more of electrical signals, optical signals, combinations thereof, and the like. As will be discussed in further detail herein, the second communication link 124 may carry data packets that include reformatted data that has been generated by the data reformat unit 128 of the network device 104.

In some embodiments, the first device interface 116 and/or second device interface 116 may include a single communication port, multiple communication ports, a serial data interface, a PCIe, an Ethernet port, an InfiniBand (TB) port, etc. The first communication link 120 and/or second communication link 124 may be established using a networking cable, an optical fiber, an electrical wire, a trace, a serial data cable, an Ethernet cable, or the like. The first communication link 120 and/or second communication link 124 may utilize any type of known or yet-to-be-developed communication protocol (e.g., packet-based communication protocol, serial communication protocol, parallel communication protocol, etc.).

Source data access and/or target data access may be achieved over a system bus (e.g., locally), over a network port (e.g., remotely), or neither (e.g., for an on-device memory). While various embodiments will be depicted or described in connection with a particular type of data access, it should be appreciated that the claims are not limited to any particular type of data access.

The data source 108 and/or data target(s) 112 may correspond to or include any type of known computational device or collection of computational devices. A data source 108, for example, may include a host device, an on-network device memory, a peer device memory, etc. A data target 112, for example, may include a host memory device, an on-network device memory, a peer device memory, etc. In some embodiments, that data target(s) 112 may be located in proximity with the network device 104 (e.g., a physical cable may be used to directly connect a data target 112 with the network device 104). In some embodiments, as shown in FIG. 1B, one or more data target 112 may be located remotely from the network device 104 and the data reformat unit 128 of the network device 104. Specifically, the data target(s) 112 may be connected to the network device 104 via a communication network 148 without departing from the scope of the present disclosure. FIG. 1B also illustrates an optional communication network 148 positioned between the data source 108 and the network device 104. It should be appreciated that the data source 108 may be remotely located from the network device 104, in which case a communication network 148 may be provided between the data source 108 and network device 104. In any configuration, the network device 104 may be configured to utilize the data reformat unit 128 to offload at least some data reformat operations that would otherwise be performed in a data target 112.

FIG. 1C illustrates a possible system 100 architecture that includes a data reformat unit 128 at a sender-side network device 104 as well as a data reformat unit 128 at a receiver-side network device 104. The data reformat unit 128 at the sender-side network device 104 may also be referred to as a source reformat unit 128. The data reformat unit 128 at the receiver-side network device 104 may also be referred to as a target reformat unit 128. Data reformatting operations depicted and described herein may be performed at the source reformat unit 128 and/or the target reformat unit 128. In some embodiments, the source reformat unit 128 may be configured to reformat data received from a data source 108 based on a source descriptor 152 whereas the target reformat unit 128 may be configured to reformat data travelling toward a data target 112 based on a target descriptor 156. While the source descriptor 152 and target descriptor 156 may be similar in content (e.g., both may contain information that enables the data reformat unit 128 to know what type of reformat operation to perform), the particular type of reformat operation performed at the sender-side network device 104 may be different from the type of reformat operation performed at the receiver-side network device 104. Because of the possibility of different reformat operations being performed at different sides of the network 148, the demand for a source descriptor 152 that is different from the target descriptor 156 arises.

In some embodiments, the receiver-side network device 104 may be unaware of the data reformat operation performed by the data reformat unit 128. Unawareness may be a strong advantage for software ecosystems and can mean that the software doesn't have to change, be redesigned, and/or re-tested when the data format is changed. Format-unawareness allows scalability and agility of the applications or distributed applications. Different applications that were targeted to perform the same semantic operations that were not designed using a single data format, can be interoperable using the network device 104 depicted and described herein. Instead of changing an application to support different data formats, the application may remain unchanged and all data format operations are aligned by the data reformat unit 128 performing operations at the network device 104.

Examples of a data source 108 and/or data target 112 include, without limitation, a host device, a server, a network appliance, a data storage device, a camera, a neural network, a Deep Neural Network (DNN), or combinations thereof. A data source 108 and/or data target 112, in some embodiments, may correspond to one or more of a Personal Computer (PC), a laptop, a tablet, a smartphone, a cluster, a container, or the like. It should be appreciated that a data source 108 and/or data target 112 may be referred to as a host, which may include a network host, an Ethernet host, an IB host, etc. As another specific but non-limiting example, one or more of the data source 108 and/or data target(s) 112 may correspond to a server offering information resources, services and/or applications to user devices, client devices, or other hosts in the computational system 100. It should be appreciated that the data source 108 and/or data target(s) 112 may be assigned at least one network address (e.g., an Internet Protocol (IP) address) and the format of the network address assigned thereto may depend upon the nature of the network to which the device is connected.

The network device 104 may correspond to an optical device and/or electrical device. The data reformat unit 128 of the network device 104 may be configured to receive data from the data source 108, collect the data received from the data source until a predetermined amount of data has been collected, perform a data reformat operation on the data after the predetermined amount of data has been collected, and then transmit the reformatted data to one or more data targets 112. In some embodiments, the data reformat unit 128 may include components that sit between different device interfaces 116. In some embodiments, the data reformat unit 128 may include components that process data received at a device interface 116 from the data source 108 and then transmit reformatted data to a data target 112 via the same device interface 116. The reformatted data may be transmitted directly to the data target(s) 112 (e.g., as shown in FIG. 1A) or the reformat data may be transmitted to the data target(s) 112 via a communication network 148 (e.g., as shown in FIG. 1B). Alternatively or additionally, data reformatting may be performed at the source reformat unit 128 and/or target reformat unit 128, meaning that the reformat operation(s) can be performed on both sides of a communication network 148 (e.g., as shown in FIG. 1C).

Components that may optionally be included as part of the data reformat unit 128 include, without limitation, a processor 132, memory 136, a buffer 140, and/or circuitry 144. The buffer 140 may correspond to an area or type of memory device that is used to collect data received from the data source 108 before the data is reformatted according to a data reformat operation. The buffer 140 may alternatively or additionally store reformatted data prior to the network device 104 transmitting the reformatted data to the data target(s) 112. The memory 136 may include instructions for execution by the processor 132 that, when executed by the processor 132, enable the data reformat unit 128 to obtain a descriptor that describes a data reformat operation to perform on the data received and collected from the data source 108. The instructions stored in memory 136 may also enable the processor 132 to provide the reformatted data (e.g., the output of the data reformat operation) to the data target(s) 112.

Additionally or alternatively, memory 136 may reside on a unit which is external to network device 104, e.g. a memory device in communication with the network device 104 via bus communication such as PCIe or CXL.

The circuitry 144 may be provided as part of the processor 132 or may be specifically configured to perform a function of the processor 132 without necessarily referencing instructions in memory 136. For instance, the circuitry 144 may include digital circuit components, analog circuit components, active circuit components, passive circuit components, or the like that are specifically configured to perform a particular data reformat operation and/or transmission process. The circuitry 144 may alternatively or additionally include switching hardware that is configurable to selectively interconnect one device interface 116 with another device interface 116 (e.g., where the network device 104 includes a switch or a component of a switch). Accordingly, the circuitry 144 may include electrical and/or optical components without departing from the scope of the present disclosure.

The network device 104 may be or may include one or more Integrated Circuit (IC) chips, microprocessors, circuit boards, CPUs, Graphics Processing Units (GPUs), Data Processing Units (DPUs), simple analog circuit components (e.g., resistors, capacitors, inductors, etc.), digital circuit components (e.g., transistors, logic gates, etc.), registers, Field Programmable Gate Arrays (FPGAs), Application Specific Integrated Circuits (ASICs), combinations thereof, and the like. It should be appreciated that the processor 132 may correspond to an optional component of the data reformat unit 128, especially in instances where the circuitry 144 provides sufficient functionality to support operations of the data reformat unit 128 described herein.

The memory 136 may include any number of types of memory devices. As an example, the memory 136 may include Random Access Memory (RAM), Read Only Memory (ROM), flash memory, Electronically-Erasable Programmable ROM (EEPROM), Dynamic RAM (DRAM), buffer 140 memory, combinations thereof, and the like. In other words, the buffer 140 may be provided as part of memory 136 without departing from the scope of the present disclosure.

Although FIGS. 1A and 1B illustrate a single data source 108 and a single box representing data target(s) 112, it should be appreciated that the network device 104 may be configured to receive data from one, two, three, . . . , or many more data sources 108 (e.g., as shown in FIG. 1C). The network device 104 may also be configured to provide reformatted data to one, two, three, . . . , or many more data targets 112 as shown in FIG. 1C. The illustration of a single data source 108 and single box representing data target(s) 112 is for illustration purposes only and should not be construed as limiting the scope of the claims. Indeed, aspects of the present disclosure contemplate the ability of the network device 104 to receive data from a single data source 108 and provide reformatted data to one or many data targets 112. The network device 104 may be configured to specify multiple different data reformats (e.g., on the same data received from one or more data sources 108), which produce different types of reformatted data, and each type of reformatted data may be provided to a different data target 112. As a non-limiting example, a network device 104 may receive raw images from one or more data sources 108 and then specify a number of different data reformat operations for the raw images. Each instance of the raw image reformatted according to a different data reformat operation may be provided to a different data target 112.

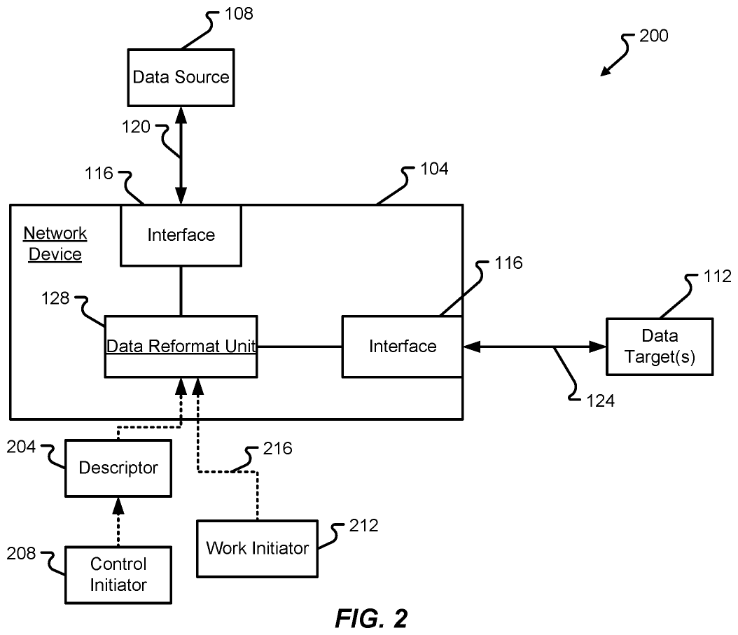

With reference now to FIG. 2, additional details of a network device 104 and a data reformat unit 128 included in a network device 104 will be described in accordance with at least some embodiments of the present disclosure. Moreover, details of a control initiator 208 and work initiator 212 and their cooperation with a network device 104 will be described in accordance with at least some embodiments of the present disclosure.

In some embodiments, a compact descriptor 204 may be prepared by a control initiator 208 and provided to the data reformat unit 128 of the network device 104. The descriptor 204 may include a description of a data reformat operation to be performed by the data reformat unit 128 prior to initiating a data reformat operation and/or prior to receiving data from a data source 108 that will have the data reformat operation applied thereto. The data reformat unit 128 may store the descriptor 204 in memory 136 so that a local description of the data reformat operation is readily available when the data reformat unit 128 begins processing data from the data source 108 for transmission to the data target(s) 112 as reformatted data. In some embodiments, the descriptor 204 may be requested by the network device 104 from the control initiator 208 when a data reformat operation is to be performed (e.g., the descriptor 204 may be retrieved in response to receiving data from the data source 108). Alternatively or additionally, the data reformat unit 128 may be initiated by a work initiator 212 transmitting a work initiation signal 216.

The data to be reformatted by the data reformat unit 128 may be received from the data source 108 and collected in the buffer 140. The data reformat operation may be initiated by the work initiator 212 whereas the descriptor 204 is provided to the network device 104 from the control initiator 208. It should be appreciated that the data source 108, control initiator 208, and work initiator 212 may be one or multiple entities. In other words, a single device may include or act as one, some, or all of the data source 108, the control initiator 208, and the work initiator 212. Alternatively, each of the data source 108, control initiator 208, and work initiator 212 may be provided in different devices. In other words, the descriptor 204 may be stored in a local memory or a remote memory, meaning that the memory containing the descriptor 204 may reside on the host node rather than on the network device 104.

The data reformat unit 128 may be configured to reformat data received from the data source 108 according to the descriptor 204 (e.g., perform a reformat operation), which describes a data reformat operation to be performed according to requirements of a data target 112 or multiple data targets 112. In other words, the descriptor 204 may provide the data reformat unit 128 with the information that enables the data reformat unit 128 to perform the appropriate data reformat operation prior to transmitting data received from the data source 108 to the data target(s) 112. As will be described in more detail below, the data target(s) 112 may correspond to a destination buffer or a network location.

In some embodiments, the descriptor 204 may assume a number of different types or formats. Illustratively, but without limitation, the descriptor 204 may include a Work Queue Element (WQE) posted to a work queue (e.g., a queue pair), a memory region description, and/or a network packet description (e.g., a description of a Remote Direct Memory Access (RDMA) request and/or a description of an application-level request). When provided as a WQE, the descriptor 204 may represent or include a single data reformat operation to be performed by the data reformat unit 128.

When provided as a memory region description, the descriptor 204 may facilitate mapping the region/reformat type once, then can be used multiple times while performing the data reformat operation. This also allows a standard RDMA READ/WRITE operation to perform high-rate data reformat operations on data in transit (e.g., data passing through the network device 104). In this example, the descriptor may be mapped once but used multiple times by a local RDMA operation performed by the network device 104.

When provided as part of a network packet, the descriptor 204 may be sent either as a type of RDMA request or encapsulated as an application-level request. This allows reformat type to be defined remotely by the RDMA work initiator 212.

As discussed above, the data source 108 may be located in host memory. Alternatively or additionally, the data source 108 may be located in an on-network device memory such that data to be reformatted by the data reformat unit 128 may be read from the on-network device memory. Alternatively or additionally, the data source 108 may be located on the network 148 such that when the data reformat request is received as part of a network packet, the data to be reformatted may also arrive as part of one or more network packets.

The data target(s) 112 may be located in host memory. Alternatively or additionally, the data target(s) 112 may be located in an on-network device memory such that reformat data may be written to the on-network device memory. In this example, the reformatted data written to the on-network device memory may be read by subsequent local RDMA operations. Alternatively or additionally, the data target(s) 112 may be located on the network 148 such that reformatted data may be written directly over the network 148 to one or more remote data targets 112.

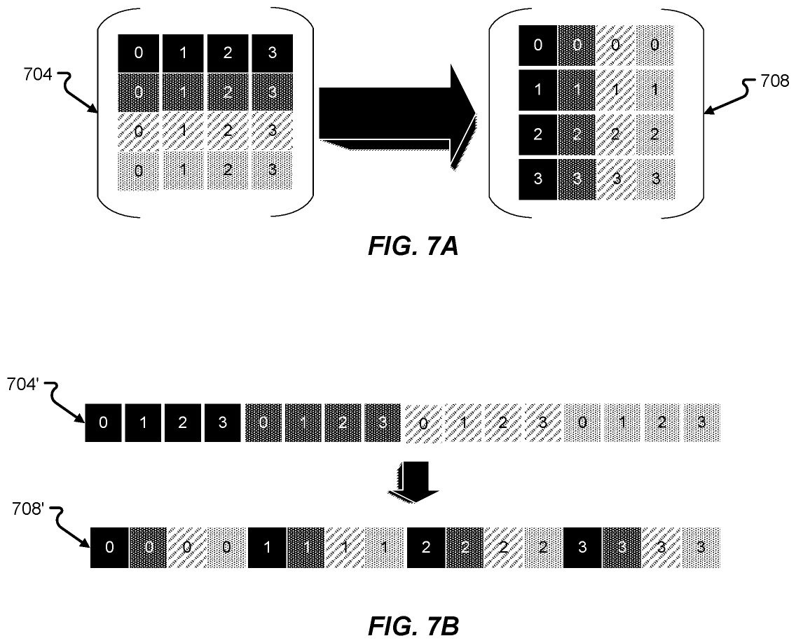

Again, there may be different types of descriptors 204. Various descriptor 204 types may be used to most efficiently describe a data reformat operation to be performed by the data reformat unit 128 of the network device 104. Non-limiting examples of data reformat operations include a matrix transpose, a non-homogeneous transpose, a removal of padding bits, an addition of padding bits, a data type conversion, a tensor layout conversion, a color channel separation, a bit packing, a component packing, and a bit tiling. Due to its homogeneous nature, a matrix transpose can be described with a relatively compact descriptor 204, which defines: (1) a number of rows; (2) a number of columns; and (3) an element size. Examples of a data reformat operation implemented as a matrix transpose are depicted in FIGS. 7A and 7B. In the example of FIG. 7A, a first matrix 704 is transposed into a second matrix 708 of the same dimensions. In other words, the first matrix 704 and second matrix 708 may each correspond to two-dimensional matrices of the same size/number of rows and columns. In the example of FIG. 7B, a first one-dimensional matrix 704′ (which is depicted as a one-dimensional representation of the first matrix 704) is transposed into a second one-dimensional matrix 708′ (which is depicted as a one-dimensional representation of the second matrix 708).

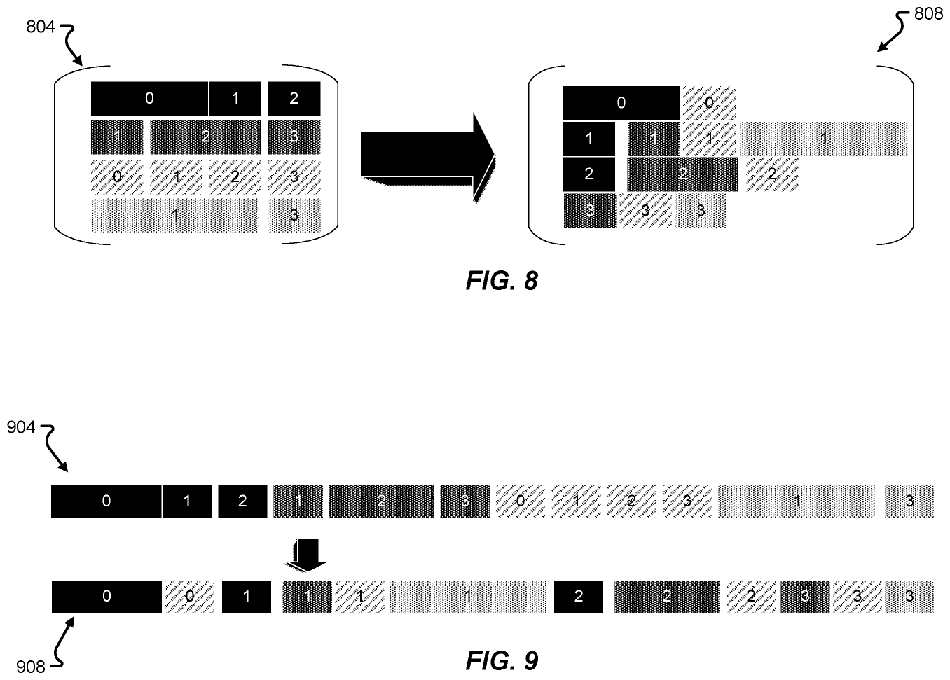

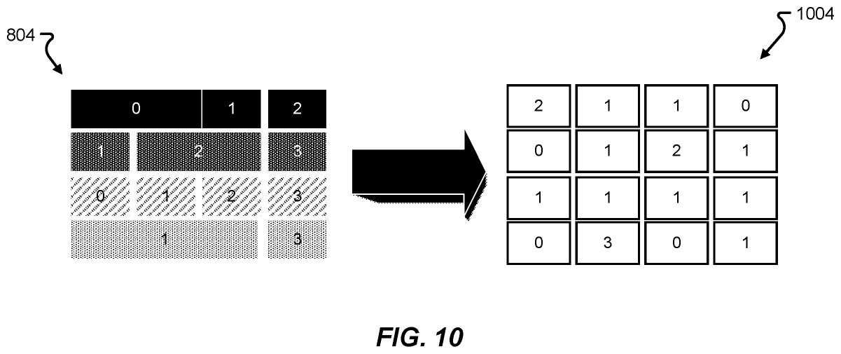

A non-homogeneous transpose may also be implemented using an appropriate descriptor 204. FIGS. 8 and 9 illustrate two examples of a non-homogenous transpose that may be implemented by the data reformat unit 128 using a descriptor 204 that describes the various element sizes in a size matrix. FIG. 8 illustrates a first matrix 804 being transposed into a second matrix 808 of a different size/dimension than the first matrix 804. In the example of FIG. 9, a first one-dimensional matrix 904 (which is depicted as a one-dimensional representation of the first matrix 804) is transposed into a second one-dimensional matrix 908 (which is depicted as a one-dimensional representation of the second matrix 808). FIG. 10 illustrates another example of a non-homogenous transpose in which the first matrix 804 can be described by a size matrix 1004. The size matrix 1004 illustratively contains the following elements (element (0,0) is size 2, element (0,1) is size 1, element (0,2) is size 1, element (0,3) is size zero, element (1,0) is size zero, . . . , etc.). A descriptor 204 can be provided that includes sufficient information to perform a non-homogeneous transpose as shown in any of FIG. 8A, 8B, or 10.

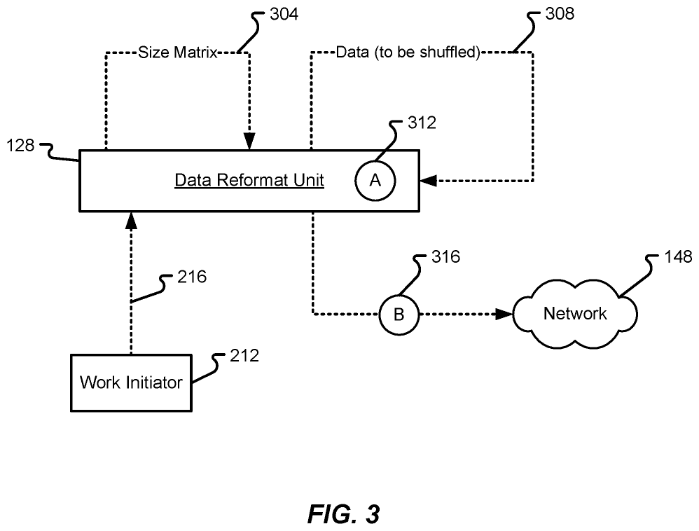

With reference now to FIGS. 3-6, additional examples of data reformat operations that may be performed by the data reformat unit 128 of the network device 104 will be described in accordance with at least some embodiments of the present disclosure. Referring first to FIG. 3, the data reformat unit 128 is shown to perform a data reformat operation on data received from a data source 108 that is located in host memory. In this particular example, the data reformat unit 128 may receive a work request 216 that includes a compact descriptor 204 and a possible size matrix 304 (which may be similar to size matrix 1004). The size matrix 304 may correspond to a pointer or inline data.

In the example of FIG. 3, the data target(s) 112 may include either host memory 312 or network-device memory 316. In the situation where the data target(s) 112 include host memory 312, the data reformat unit 128 may receive a descriptor 204 that includes a data pointer, a description of a number of rows to output in reformatted data, a description of a number of columns to output in reformat data, and/or a description of element sizes. Information provided in the descriptor 204 and used by the data reformat unit 128 to perform the data reformat operation on the data to be reformatted 308 (e.g., the data received and collected from the data source 108) may enable the data reformat unit 128 to perform the data reformat operation prior to transmitting the reformatted data to the data target(s) 112. The data to be reformatted 308 may include electronic data in any number of different data formats. Non-limiting examples of data to be reformatted 308 include processed images, raw images, compressed images, data files, pixel data, combinations thereof, and the like. Illustratively, the data reformat unit 128 may be configured to process pixel data and perform a data reformat operation that results in bit-packing, pixel reordering, pixel regrouping, etc. Alternatively or additionally, the data reformat unit 128 could be configured to perform typecasting or the like (e.g., changing data from a format like floating point-32 (FP32) to another format like floating point-28 (FP8)), which results in a data reduction. This may be performed as part of a data reformat operation or in addition to performing a data reformat operation.

In one option, the data 308 reformatted by the data reformat unit 128 (e.g., reformatted data 312) may be written to host memory to enable local CPU operation acceleration. Alternatively or additionally, the data 308 reformatted by the data reformat unit 128 (e.g., reformatted data 316) may be stored in the network-device memory when staging data as a preparation for subsequent network operations (e.g., RDMA WRITE or READ). Alternatively or additionally, the data 308 reformatted by the data reformat unit 128 (e.g., reformat data 316) may be sent across the network 148. In this example, the information provided in the descriptor 204 may enable an all-to-all operation and may include a data pointer and a size matrix pointer. Additional details of an all-to-all operation are provided in U.S. Patent Publication No. 2018/0367589, the entire contents of which are hereby incorporated herein by reference.

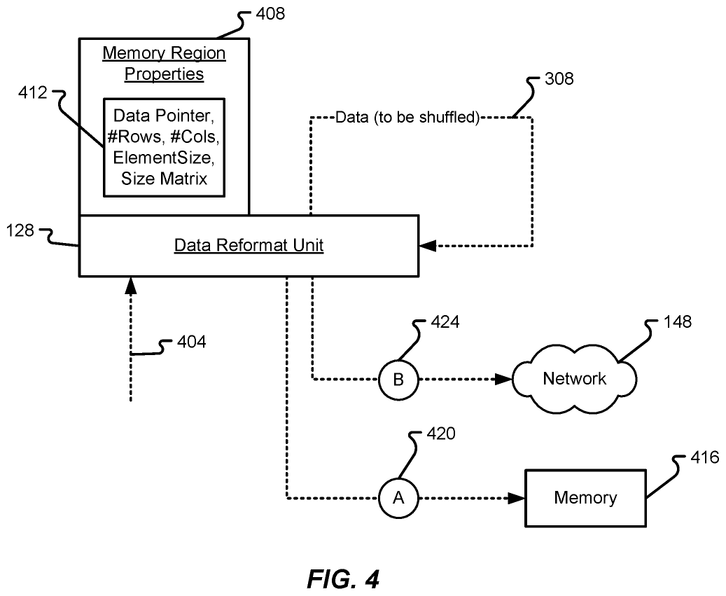

With reference now to FIG. 4, the data reformat unit 128 is shown to perform a data reformat operation on a work request 216 that is a local DMA request or RDMA request 404. The data reformat unit 128 may be provided with a descriptor 204 including memory region properties 408. The memory region properties 408 provided as part of the descriptor 204 may include parameters 412 such as a data pointer, a description of a number of rows to output in reformatted data, a description of a number of columns to output in reformatted data, a description of element sizes, and/or a size matrix. The data pointer, description of the number of rows to output in the reformatted data, description of the number of columns to output in the reformatted data, and the description of element size may be used when reformatted data 420 is written to local memory 416. The data pointer and size matrix may be used when reformatted data 424 is provided to the network 148.

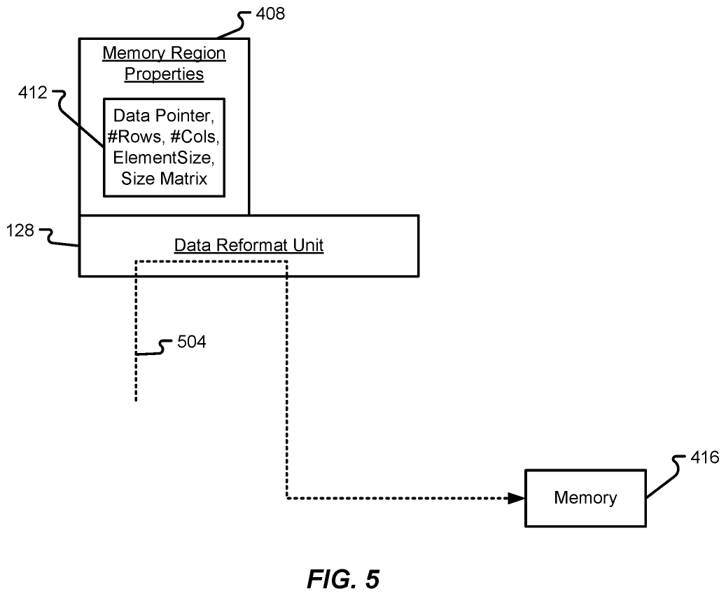

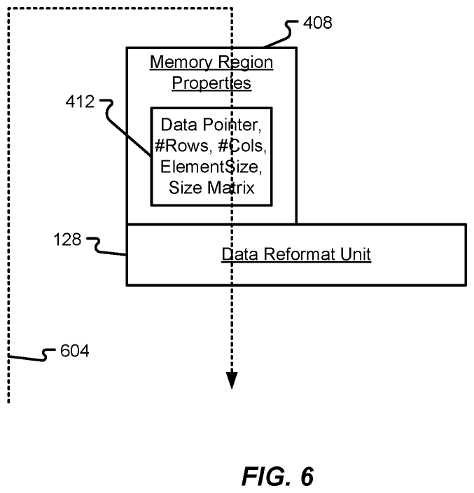

In the example of FIGS. 5 and 6, the data reformat unit 128 is shown to perform a REMOTE operation. Here the work request 216 received at the data reformat unit 128 illustratively includes an RDMA WRITE request 504 or RDMA READ request 604. Like the example of FIG. 4, the memory region properties 408 contains a description of the data reformat manipulation to be performed by the data reformat unit 128. The data transfer can be initiated, for example, using the RDMA READ request 504 where the memory region 408 is either the data source 108 or data target 112 of the RDMA operation. Here also, the data received from the data source 108 may arrive from the network 148 or be read from host memory. The data reformat unit 128 may respond to the request 504 by shuffling data from the data source 108 and providing the reformatted data to memory 416. Alternatively, for an RDMA READ request 604, the network device 104 may provide the reformat data over the network 148.

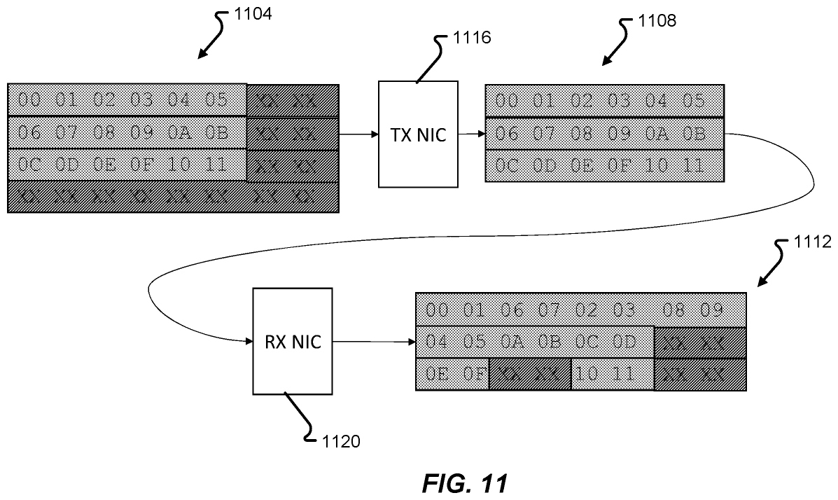

Yet another example of a data reformat operation that may be performed by one or more network devices 104 will be described with reference to FIG. 11. In this particular example, a transmitting NIC 1116 and receiving NIC 1120 are shown to work in cooperation with one another to perform a pitch-linear->unpadded->tiled data reformat operation. The transmitting NIC 1116 and receiving NIC 1120 may both correspond to examples of a network device 104 without departing from the scope of the present disclosure. Specifically, both the transmitting NIC 1116 and receiving NIC 1120 may include a data reformat unit 128.

In some embodiments, a first matrix 1104 is shown as a pitch-linear surface with padding to width and possibly to height to machine words. As an example, the first matrix 1104 may include image data that is stored in raster order. The transmitting NIC 1116 may receive the first matrix 1104 and invoke its data reformat unit 128, which references an appropriate descriptor to implement a data reformat operation. The data reformat operation may be performed to format the data from the first matrix 1104 according to a data format requirement of a data target (e.g., the receiving NIC 1120 or a device in communication with the receiving NIC 1120). Upon referencing a descriptor available to the transmitting NIC 1116, the data reformat unit 128 of the transmitting NIC 1116 may remove the padding of the first matrix 1104 prior to transmitting first reformatted data (e.g., as a second matrix 1108) across a communication network. Transmitting unpadded data as compared to the first matrix 1104 may help to minimize undesirable bandwidth usage.

At the opposite side of the network, the receiving NIC 1120 may receive the first reformatted data and invoke its data reformat unit 128 to store additional reformatted data (e.g., as a third matrix 1112). The third matrix 1112 may include the original data from the first matrix 1104 in a tiled order with padding appropriate for another computational device (e.g., a downstream accelerator).

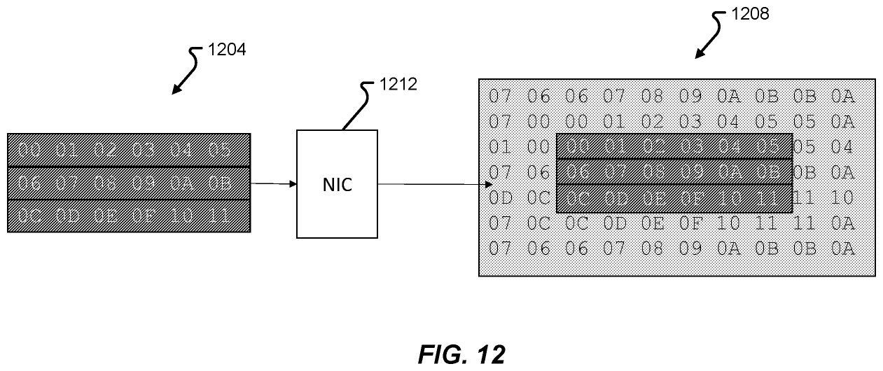

FIG. 12 illustrates yet another example of a data reformat operation that may be performed by a data reformat unit 128 of a NIC 1212 in accordance with at least some embodiments of the present disclosure. The NIC 1212 may correspond to another example of a network device 104 having a data reformat unit 128 configured to receive data in a first format, reformat the data according to a descriptor, and then transmit the reformatted data.

In the example of FIG. 12, the NIC 1212 receives image data in the format of a first matrix 1204. Here the NIC 1212 may be configured to perform a data reformat operation that creates a border extension. Image borders can sometimes require special handling for post-processing. If hardware support for these cases is not available internally to an accelerator, then significant performance can be lost or quality is reduced. These issues can be addressed by utilizing the NIC 1212 to perform a data reformat operation that extends the borders of the first matrix 1204, thereby creating reformatted data in the form of a second matrix 1208. The second matrix 1208 represents the first matrix 1204, but with extended borders. The borders may be extended according to different policies and filter size (which may be defined in the descriptor 204). Examples of different policies that may be accommodated with use of the NIC 1212 include, without limitation, constant padding, mirroring, continuation, etc.

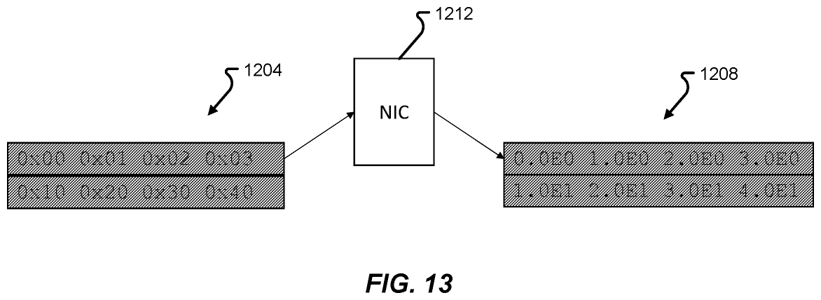

FIG. 13 illustrates still another example of a NIC 1212 performing a data type conversion when implementing a data reformat operation. It is possible that algorithms (which may be implemented at different data target(s) 112) have a different requirement on input data type. The NIC 1212 may be configured to accommodate the various input data type requirements of different data target(s) 112 by implementing a data reformat operation for each data target 112. One, some, or all of the different input data type requirements may be different from the data format used by a data source 108 (e.g., a camera). For example, source data 1204 from a camera may be consumed by a data target 112 (e.g., a neural network) expecting a 32-bit floating point. The NIC 1212 may be configured to perform the appropriate data conversion on the source data 1204 to produce reformatted data 1208 having the format expected and required by the data target 112. The NIC 1212 may be configured to perform the data reformat operation inline, thereby enabling the data target 112 to immediately start processing the reformatted data 1208 without performing its own data type conversion. Another example of a data type conversion that may be performed by the NIC 1212 is to convert floating source data 1204 to a fixed point reformatted data 1208 (e.g., normalized 0-1 fixed point).

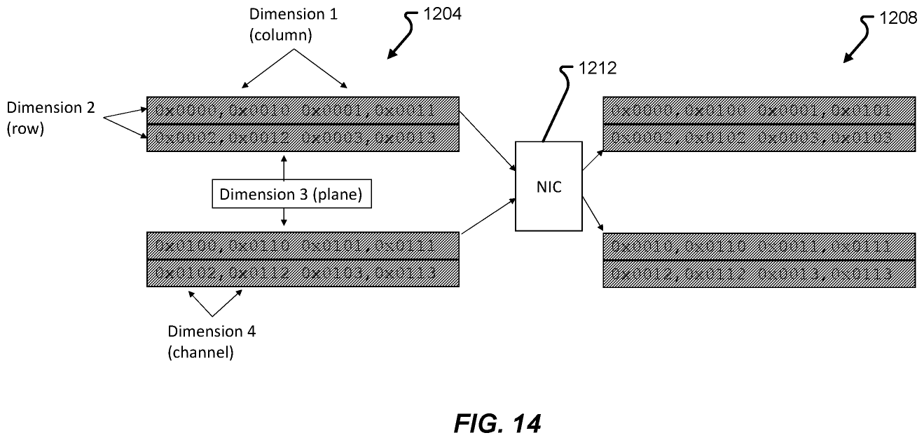

FIG. 14 illustrates a NIC 1212 that is configured to perform a tensor layout conversion in accordance with at least some embodiments of the present disclosure. Here again, the NIC 1212 is configured to perform a data reformat operation that causes a first matrix 1204 to be reformatted to a second matrix 1208 of a different format than the first matrix 1204. This data reformat operation may be performed inline and while the NIC 1212 is transmitting the data from a data source 108 to a data target 112.

Tensors are high-dimensional objects used for DNNs. The representation of the data (ordering of dimensions, packing, etc.) is coupled with DNN design. In this example, the NIC 1212 is configured to convert between tensor layouts as part of data transfer in a distribute Artificial Intelligence (AI) application to facilitate interoperation of different neural networks or neural network types.

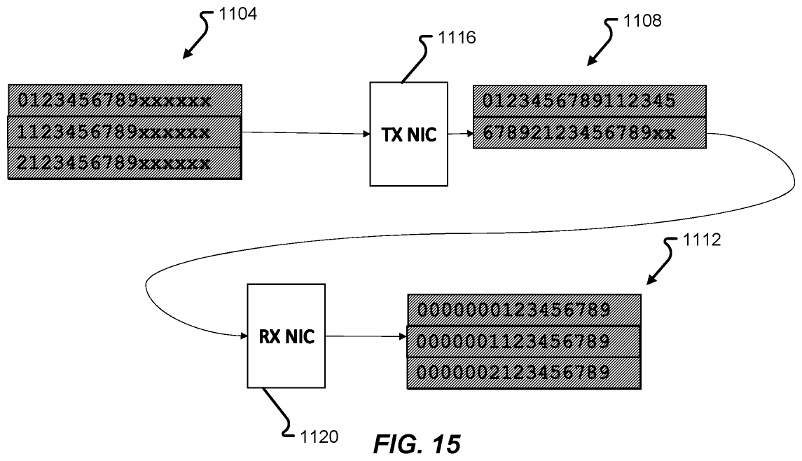

FIG. 15 illustrates a transmitting NIC 1116 and receiving NIC 1120 that are configured to cooperate with one another and perform data reformat operations that result in bit packing. As a specific but non-limiting example, deep color image data is often stored with padding bits in each word. In this example, the first matrix 1104 includes 10-bit data stored at 10 most significant bits and zero bits padded at the end to make a 16-bit word. The padding of the first matrix 1104 can be modified by the transmitting NIC 1116 if the data reformat unit 128 of the transmitting NIC 1116 is aware of the data padding and is configured to perform a data reformat operation that reduces the padding, thereby producing a second matrix 1108 that has reduced padding. The second matrix 1108 can be transmitted across a network with less bandwidth and may be stored with less storage costs.

The receiving NIC 1120 may then utilize its data reformat unit 128 to strip out padding X for transmission (RGBA, YUVX) endianness in general and produce a third matrix 1112. In this example, the descriptor 204 made available to the receiving NIC 1120 to produce the third matrix 1112 may define a requirement for endianness. In the case of endianness, for example, the endianness doesn't change “on the fly” and it may be possible to utilize a general descriptor 204 with a rule, on which packets/jobs are applied. In one possible application, the transmitting NIC 1116 may be provided in a network border or network edge device that transmits data to the cloud. By reducing bit rate with the transmitting NIC 1116, the overall bandwidth required to carry the data from the data source 108 to the data target 112 can be reduced.

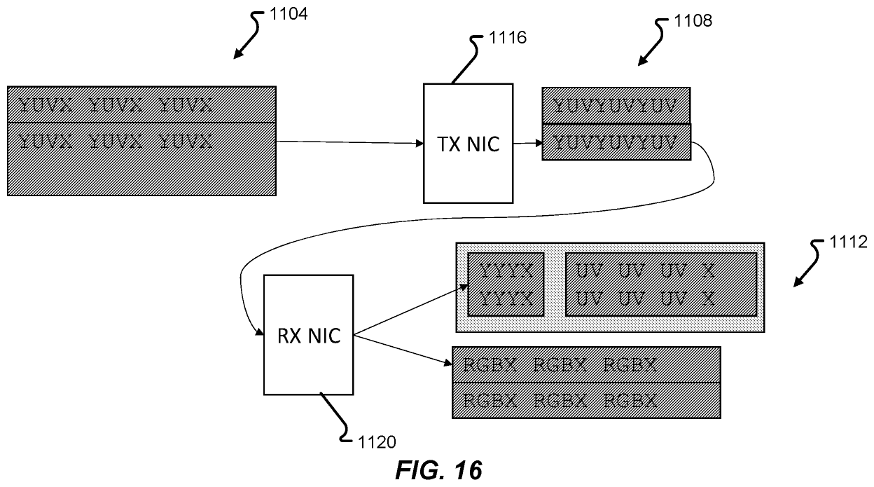

FIG. 16 illustrates still another example where a transmitting NIC 1116 and receiving NIC 1120 cooperate with one another to facilitate component packing and multiple write operations. Data storage formats may have unused channels for word alignment. Multiple formats may be needed on the receiving side (e.g., at the output of the receiving NIC 1120) for different engines. Format conversions implemented by the transmitting NIC 1116 and receiving NIC 1120 could include standard transformation (e.g., YUV full-swing to studio-swing conversions or YUV to sRGB conversions). Here again, the first matrix 1104 may be reformatted by the transmitting NIC 116 to produce a second matrix 1108, which is transmitted to the receiving NIC 1120. The receiving NIC 1120 may then perform a data reformat operation on the second matrix 1108 to produce reformatted data in the format illustrated by the third matrix 1112 (or matrices).

One possible use case for the example of FIG. 16 may include a situation where a DNN and traditional neural network operate in parallel on a common data target 112 with different layout requirements. In another possible example, different requirements between video encode (studio swing) and compute (full swing) accelerators can be accommodated by the transmitting NIC 1116 and receiving NIC 1120 performing data reformat operations as shown. The architecture of FIG. 16 may also be useful to support special requirements for endianness, packing for data authentication separate from the compute node.

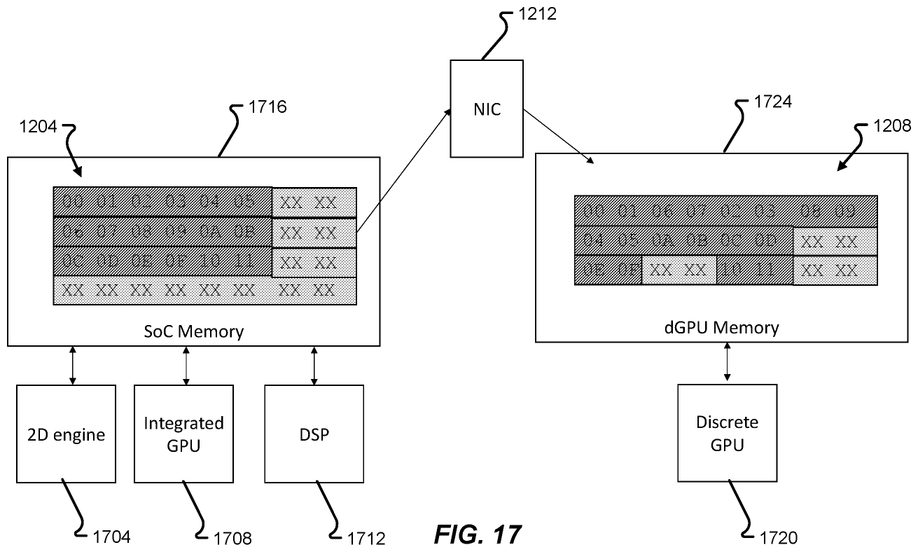

FIG. 17 illustrates yet another example in which NIC 1212 is configured to transfer data from one memory sub-system to another memory sub-system in accordance with at least some embodiments of the present disclosure. In this example, the NIC 1212 is configured to receive data from a data source in first format (e.g., as the first matrix 1204), perform a data reformat operation on the received data, then transfer the reformatted data to a data target in a second format (e.g., as the second matrix 1208).

In this example, the data source 108 and data target 112 may correspond to different memory sub-systems in a vehicle. The NIC 1212 may be configured to perform a format conversion inline to allow direction operation by accelerators in each system. Illustratively, the first memory sub-system is shown to include a two-dimensional engine 1704, an integrated GPU 1708, and a Digital Signal Processor (DSP) 1712. The first memory sub-system further includes System on Chip (SoC) memory 1716. Collectively, the two-dimensional engine 1704, the integrated GPU 1708, the DSP 1712, and the SoC memory 1716 may constitute the first memory sub-system and may be considered a data source 108 to the NIC 1212.

The second memory sub-system may include a discrete GPU 1720 and a GPU memory 1724. The second memory sub-system may be considered a data target 112 to the NIC 1212. By performing data reformat operations in the NIC 1212, the first and second memory sub-systems are relieved, at least partially, of the overhead associated with performing the data reformat operation.

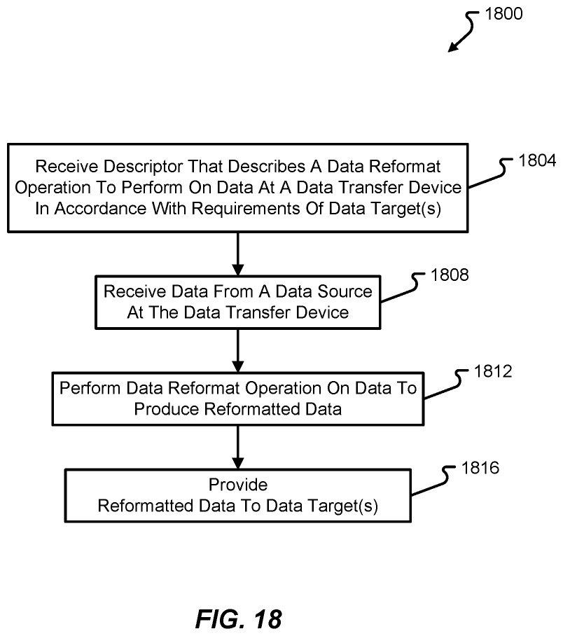

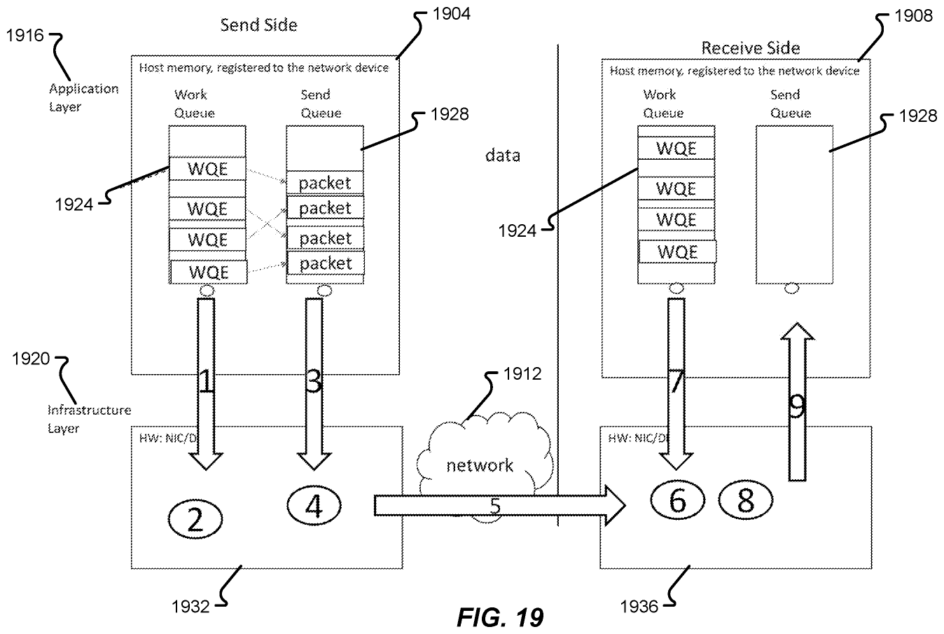

Referring now to FIG. 18, various methods will be described in accordance with at least some embodiments of the present disclosure. The disclosed methods will be described in a particular order and/or as being performed by particular components of a system 100, but it should be appreciated that the steps of method(s) may be performed in any suitable order (or in parallel), may be combined with step(s) from other method(s), and/or may be performed by other components described herein.

One method 1800 is illustrated in FIG. 18, which begins when a descriptor 204 is received at a data reformat unit 128 (step 1804). The descriptor 204 may include information that describes a data reformat operation to perform on data at the device including the data reformat unit 128. In some embodiments, the descriptor 204 may describe the data reformat operation to perform in accordance with one or more requirements or processing needs of data target(s) 112. The descriptor 204 may be received prior to receiving data to be reformatted or may be requested/retrieved in response to receiving data to be reformatted.

The method 1800 continues when data is received at the network device 104 from a data source 108 (step 1808). The data may be received in a first format (e.g., as a first matrix) and may be received at a first device interface 116 that enables communications between the network device 104 and data source 108.

The method 1800 continues with the network device 104 invoking the data reformat unit 128 to perform the data reformat operation on the data, thereby producing reformatted data (step 1812). In some embodiments, the data reformat operation is performed based on information contained in the descriptor 204 and is performed while the network device 104 is in the process of relaying data from the data source 108 to the data target 112.

The method 1800 may then continue with the network device 104 providing the reformat data to one or more data targets 112 (step 1816). The reformatted data may be provided to a local data target 112 and/or remote data target 112.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A data transfer device, comprising:
a first device interface enabling communications with a data source;
a second device interface enabling communications with a data target; and
a data reformat unit, comprising:
circuitry that collects data received from the data source, references a descriptor that describes a data reformat operation to perform on the data received from the data source, reformats the data received from the data source according to the data reformat operation, and provides the reformatted data to the data target via the second device interface.

2. The data transfer device of claim 1, wherein the descriptor is stored in a local memory or a remote memory and described by a match criteria on the data.

3. The data transfer device of claim 1, wherein the descriptor is provided by at least one of the data source and the data target.

4. The data transfer device of claim 1, wherein the descriptor is referenced for a plurality of data reformat operations.

5. The data transfer device of claim 1, wherein the first device interface comprises a communication port connected with a communication network.

6. The data transfer device of claim 5, wherein the second device interface comprises an additional communication port connected with a communication network.

7. The data transfer device of claim 5, wherein the second device interface connects to a communication network.

8. The data transfer device of claim 1, wherein the first device interface connects to a communication network.

9. The data transfer device of claim 1, wherein the data source and data target are accessed via a single device interface.

10. The data transfer device of claim 1, wherein the first device interface and the second device interface are the same interface.

11. The data transfer device of claim 10, wherein the data source and the data target use the same memory area.

12. The data transfer device of claim 10, wherein no data target address is provided, and the device writes the reformatted data to the source address.

13. The data transfer device of claim 10, wherein the data received from the data source comprises a neural network.

14. The data transfer device of claim 1, wherein the data received from the data source comprises image data.

15. The data transfer device of claim 1, wherein the data received from the data source is formatted for use by a first version of an application and wherein the reformatted data is formatted for use by a second version of the application.

16. The data transfer device of claim 1, wherein the data reformat operation comprises at least one of a matrix transpose, a non-homogenous transpose, a data type conversion, a tensor layout conversion, color channel separation, and a change in endianity.

17. The data transfer device of claim 1, wherein the device is a network interface adapter or a DPU (data processing unit).

18. The data transfer device of claim 1, wherein an initiator of the data reformat operation is the data source.

19. The data transfer device of claim 1, wherein an initiator of the data reformat operation is the data target.

20. The data transfer device of claim 1, wherein an initiator of the data reformat operation is an infrastructure layer.

21. The data transfer device of claim 1, wherein the circuitry of the data reformat unit is further configured to perform the data reformat operation on the data received from the data source and produce first reformatted data for the data source as well as second reformatted data from an additional data source, wherein the first reformatted data is formatted differently from the second reformatted data.

22. The data transfer device of claim 1, wherein the descriptor defines a requirement for endianness.

23. The data transfer device of claim 1, wherein at least one of the data source and data target comprise a peripheral device.

24. The data transfer device of claim 1, wherein the descriptor is stored in memory that is coupled with the circuitry or in a remote memory.

25. The data transfer device of claim 1, wherein the descriptor is received from a control device that is different from the data source and the data target.

26. A system, comprising:
circuitry; and
memory coupled with the circuitry, wherein the circuitry is configured to collect data received from a data source in the memory, reference a descriptor that describes a data reformat operation to perform on the data received from the data source, reformat the data received from the data source according to the data reformat operation, and provide the reformatted data to a data target.
